(19) United States
(12) Patent Application Publication
(10) Pub. No.: US 2009/0326843 A1
(43) Pub. Date: Dec. 31, 2009

(54) APPARATUS AND METHOD FOR DETECTING TEMPERATURE/VOLTAGE VARIATION OF SEMICONDUCTOR INTEGRATED CIRCUIT

(75) Inventor: Choung Ki Song, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 12/346,547

(22) Filed: Dec. 30, 2008

(30) Foreign Application Priority Data
Jun. 30, 2008 (KR) 10-2008-0062609

(51) Int. Cl. G01R 19/00

(52) U.S. Cl. 702/65

(57) ABSTRACT

An apparatus for detecting temperature/voltage variations of a semiconductor integrated circuit includes an oscillator configured to generate an oscillation signal whose frequency is varied according to temperature/voltage variations, and a code generator configured to generate a code signal using the oscillation signal, wherein the code signal is used as a criterion for detecting the temperature/voltage variations in a circuit construction exterior of the apparatus for detecting the temperature/voltage variations.

### CROSS-REFERENCES TO RELATED PATENT APPLICATION

The present application claims priority under 35 U.S.C 119(a) to Korean Application No. 10-2008-0062609, filed on Jun. 30, 2008, in the Korean Intellectual Property Office, which is incorporated herein by reference in its entirety as if set forth in full.

### BACKGROUND

1. Technical Field

The embodiments described herein relate to a semiconductor integrated circuit (IC), and more particularly, to an apparatus and a method for detecting temperature/voltage variation of a semiconductor IC.

2. Related Art

In general, semiconductor ICs are designed to have sufficient operational timing margin based on the maximum variation range of a temperature/voltage to ensure a stable operation of the semiconductor ICs. However, the semiconductor ICs cannot detect temperature/voltage variations, and thus, have been designed to have sufficient operational timing margin in the actual operational timing.

In the semiconductor ICs, an increase of operational timing margin can deteriorate high-speed operations of the semiconductor IC. Moreover, the high-speed operations of the semiconductor ICs become more complex as the speed of external clock signals gradually become faster. Thus, an apparatus and a method for detecting temperature/voltage variation of a semiconductor IC that can detect temperature/voltage variation is required.

### SUMMARY

An apparatus and a method for detecting temperature/voltage variations of a semiconductor IC are described herein.

In one aspect, an apparatus for detecting temperature/voltage variations of a semiconductor integrated circuit includes an oscillator configured to generate an oscillation signal whose frequency is varied according to temperature/voltage variations, and a code generator configured to generate a code signal using the oscillation signal, wherein the code signal is used as a criterion for detecting the temperature/voltage variations in a circuit construction exterior of the apparatus for detecting the temperature/voltage variations.

In another aspect, an apparatus for detecting temperature/voltage variation of a semiconductor integrated circuit includes a driver configured to generate a driving signal according to an enable signal and a timing control clock signal, an oscillator configured to generate an oscillation signal during a period where the driving signal is activated, a code generator configured to output a value obtained by counting the oscillation signal as a reserved code signal, and a code output unit configured to latch one of a whole and partial bits of the reserved code signal according to the timing control clock signal, and to output the latched result as a temperature/voltage variation detection code signal.

In another aspect, a method for detecting temperature/voltage variations of a semiconductor integrated circuit includes generating an oscillation signal, and generating a code signal using the oscillation signal to output the code signal used as a criterion for detecting temperature/voltage variations of a semiconductor integrated circuit.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a schematic block diagram of an exemplary apparatus for detecting temperature/voltage variations of a semiconductor IC according to one embodiment;

FIGS. 2A and 2B are schematic circuit diagrams of exemplary first and second drivers, each capable of being implemented in the apparatus of FIG. 1 according to one embodiment;

FIG. 3 is a schematic circuit diagram of an exemplary oscillator capable of being implemented in the apparatus of FIG. 1 according to one embodiment;

FIG. 4 is a schematic circuit diagram of an exemplary code generator capable of being implemented in the apparatus of FIG. 1 according to one embodiment;

FIG. 5 is a schematic circuit diagram of an exemplary divider capable of being implemented in the apparatus of FIG. 1 according to one embodiment;

FIG. 6 is a schematic circuit diagram of an exemplary timing control clock generator capable of being implemented in the apparatus of FIG. 1 according to one embodiment;

FIG. 7 is a schematic circuit diagram of an exemplary code output unit capable of being implemented in the apparatus of FIG. 1 according to one embodiment;

FIG. 8 is a schematic circuit diagram of an exemplary code valid signal generator capable of being implemented in the apparatus of FIG. 1 according to one embodiment; and

FIG. 9 is a view illustrating exemplary waveforms output from an apparatus for detecting temperature/voltage variations of a semiconductor IC according to one embodiment.

### DETAILED DESCRIPTION

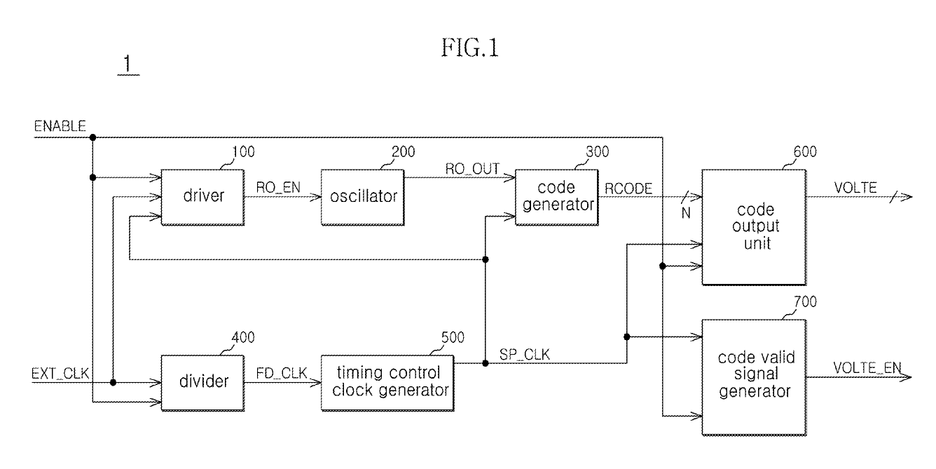

FIG. 1 is a schematic block diagram of an exemplary apparatus for detecting temperature/voltage variations of a semiconductor IC according to one embodiment. In FIG. 1, an apparatus 1 for detecting temperature/voltage variations of a semiconductor IC can be configured to include a driver 100, an oscillator 200, a code generator 300, a divider 400, a timing control clock generator 500, a code output unit 600, and a code valid signal generator 700.

The driver 100 can be configured to synchronize an enable signal ‘ENABLE’ with an external clock signal ‘EXT_CLK’ according to a timing control clock signal ‘SP_CLK’ to generate a driving signal ‘RO_EN’.

The oscillator 200 can be configured to be operated according to the driving signal ‘RO_EN’ to generate an oscillation signal ‘RO_OUT’. In addition, the code generator 300 can be configured to count the oscillation signal ‘RO_OUT’ to generate a reserved code signal ‘RCODE’ and to initialize the reserved code signal ‘RCODE’ according to the timing control clock signal ‘SP_CLK’.

The divider 400 can be configured to divide the external clock signal ‘EXT_CLK’ by a predetermined division ratio to generate a division clock signal ‘FD_CLK’ and to initialize the division clock signal ‘FD_CLK’ according to the enable signal ‘ENABLE’. In addition, the timing control clock generator 500 can be configured to generate the timing control clock signal ‘SP_CLK’ at a specific edge, for example, a falling edge, of the division clock signal ‘FD_CLK’.

The code output unit 600 can be configured to output the bits other than specific bits of the reserved code signal ‘RCODE’ as a temperature/voltage variation detection code signal ‘VOLTE’ according to the timing control clock signal ‘SP_CLK’. In addition, the code output unit 600 can be configured to initialize the temperature/voltage variation detection code signal ‘VOLTE’ according to the enable signal ‘ENABLE’. The overall bits of the reserved code signal ‘RCODE’ can also be used as the temperature/voltage variation detection code signal ‘VOLTE’. However, as the number of bits of the temperature/voltage variation detection code signal ‘VOLTE’ increases, the size and the signal loading of circuit blocks using the temperature/voltage variation detection code signal VOLTE can increase and the construction of circuit can therefore be complicated. Accordingly, predetermined bits, for example, the bits other than the lower two bits, which are considered appropriate for temperature/voltage variation detection operations, can be used as the temperature/voltage variation detection code signal ‘VOLTE’. Here, the temperature/voltage variation detection code signal ‘VOLTE’ can be used for various components in the semiconductor IC that can be related to signal processes.

In FIG. 1, the code valid signal generator 700 can be considered to generate a code valid signal ‘VOLTE_EN’ according to the enable signal ‘ENABLE’ and the timing control clock signal ‘SP_CLK’. The code valid signal ‘VOLTE_EN’ is a signal that can inform the components in the semiconductor IC, which can be related to signal processes, of the validity of the temperature/voltage variation detection code signal ‘VOLTE’. For example, when the temperature/voltage variation detection code signal ‘VOLTE’ is output at the time point when the code valid signal ‘VOLTE_EN’ is activated, the temperature/voltage variation detection code signal ‘VOLTE’ can be validated. However, when the temperature/voltage variation detection code signal ‘VOLTE’ is output at the time point when the code valid signal ‘VOLTE_EN’ is inactivated, the temperature/voltage variation detection code signal ‘VOLTE’ can be invalidated.

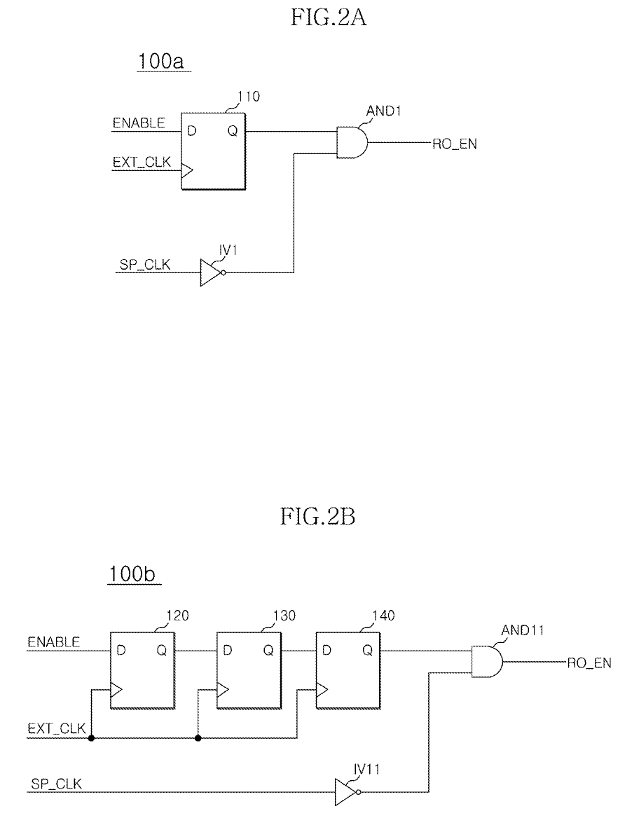

FIGS. 2A and 2B are schematic circuit diagrams of exemplary first and second drivers 100a and 100b, each capable of being implemented in the apparatus of FIG. 1 according to one embodiment. In FIGS. 2A and 2B, the first driver 100a and the second driver 100b can be configured to have various forms. When the enable signal ‘ENABLE’ is generated, for example, using a Mode Register Set (MRS), the first driver 100s can be used. When the enable signal ‘ENABLE’ is input directly from an exterior of the semiconductor IC, the driver 100b can be used.

In FIG. 2A, the driver 100a can include a flip-flop 110, an inverter IV1, and an AND gate AND1. The driver 100a can cause the enable signal ‘ENABLE’ to be synchronous with the external clock signal ‘EXT_CLK’, and can output the synchronized signal as the driving signal ‘RO_EN’ when the timing control clock signal ‘SP_CLK’ is inactivated. The driver 100a can inactivate the driving signal ‘RO_EN’ regardless of the enable signal ‘ENABLE’ when the timing control clock signal ‘SP_CLK’ is activated. Since the period where the timing control clock signal ‘SP_CLK’ is activated can substantially equal the timer period where the reserved code signal ‘RCODE’ is initialized, the oscillator 200 does not need to be operated. Accordingly, the driver 100a can been configured so that the driving signal ‘RO_EN’ can be inactivated regardless of the enable signal ‘ENABLE’ when the timing control clock signal ‘SP_CLK’ is activated.

In FIG. 2B, the driver 100b can be configured to include a plurality of flip-flops 120 to 140, an inverter IV11, and an AND gate AND11. Here, the driver 100b can be configured to operate in substantially the same way as the driver 100a (in FIG. 2A). However, the only difference is that the number of flip-flops has been increased to be more in the driver 100b than in the driver 100a in order to compensate for timing errors between the enable signal ‘ENABLE’, which can be internally generated, and the enable signal ‘ENABLE’, which can be externally input.

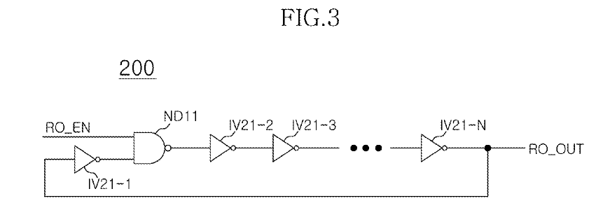

FIG. 3 is a schematic circuit diagram of an exemplary oscillator 200 capable of being implemented in the apparatus of FIG. 1 according to one embodiment. In FIG. 3, the oscillator 200 can include a chain of a plurality of inverters IV21-1 to IV21-N and a NAND gate ND11.

The oscillator 200 can generate the oscillation signal ‘RO_OUT’ when the driving signal ‘RO_EN’ is activated, and can maintain the oscillation signal ‘RO_OUT’ as an inactivation level, for example, a low level, when the driving signal ‘RO_EN’ is inactivated.

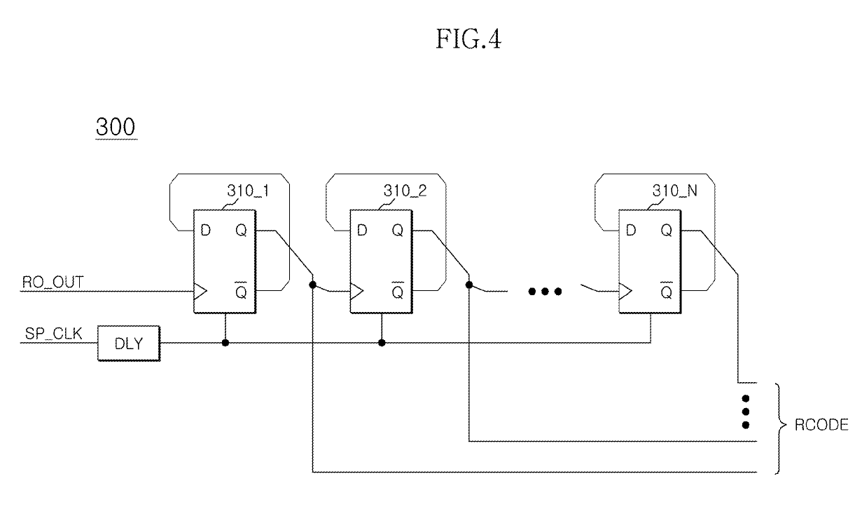

FIG. 4 is a schematic circuit diagram of an exemplary code generator 300 capable of being implemented in the apparatus of FIG. 1 according to one embodiment. In FIG. 4, the code generator 300 can be configured as a counter to include a plurality of flip-flops 310-1 to 310-N and a counter having a delay component DLY. The plurality of flip-flops 310-1 to 310-N can output the reserved code signals ‘RCODE’ through their output terminals Q, and the flip-flop 310-1 can receive the oscillation signal ‘RO_OUT’ through the clock terminal. Here, the clock terminal of each of the plurality of flip-flops 310-2 to 310-N can be connected to the output terminal Q of another flip flop located immediately before it. The inverse output terminal /Q of each of the plurality of flip-flops 310-1 to 310-N can be connected to its own input terminal D. The reserved code signal ‘RCODE’ can be initialized according to the timing control clock signal ‘SP_CLK’ delayed by the delay component DLY. The use of the delay component can prevent the reserved code signal ‘RCODE’ from being initialized before the reserved code signal ‘RCODE’ is latched to the code output unit 600 according to the timing control clock signal ‘SP_CLK’.

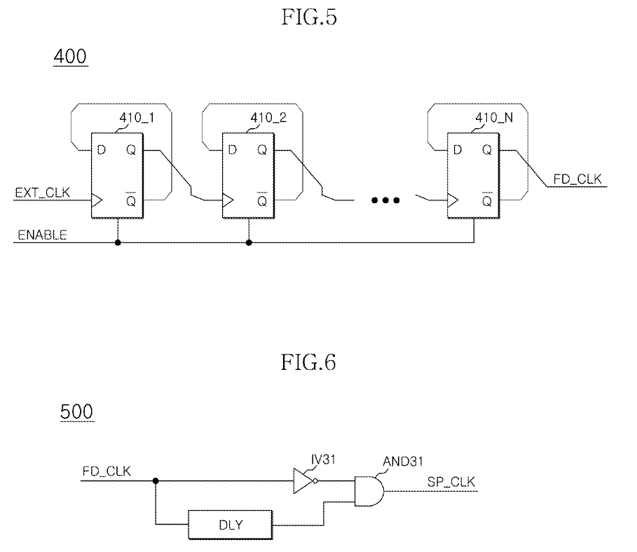

FIG. 5 is a schematic circuit diagram of an exemplary divider 400 capable of being implemented in the apparatus of FIG. 1 according to one embodiment. In FIG. 5, the divider 400 can be configured to include a plurality of flip-flops 410-1 to 410N. Here, a division clock signal ‘FD_CLK’, which has been divided by a predetermined division ratio, can be output through the output terminal Q of the last flip-flop 410-N among the plurality of flip-flops 410-1 to 410-N. The flip-flop 410-1 can receive an external clock signal ‘EXT_CLK’ through its clock terminal, wherein the clock terminal of each of the plurality of flip-flops 410-2 to 410-N can be connected to the output terminal Q of another flip-flop located immediately before it. The inverse output terminal /Q of each of the plurality of flip-flops 410-1 to 410-N can be commonly connected to its own input terminal D. The generation of the division clock signal ‘FD_CLK’ can be stopped according to inactivation of the enable signal ‘ENABLE’. The division ratio can be determined according to the number of the plurality of flip-flops 410-1 to 410-N. For example, the external clock signal ‘EXT_CLK’ can be divided by the factor of 4 if the number of flip-flops is 2, and by the factor of 16 if the number of flip-flops is 4.

FIG. 6 is a schematic circuit diagram of an exemplary timing control clock generator 500 capable of being implemented in the apparatus of FIG. 1 according to one embodiment. In FIG. 6, the timing control clock generator 500 can be configured to include an inverter IV31, an AND gate AND31, and a delay component DLY.

The timing control clock generator 500 can generate a timing control clock signal ‘SP_CLK’ having a width that corresponds to the delay time of the delay component DLY when the division clock signal ‘FD_CLK’ transitions from a high level to a low level.

FIG. 7 is a schematic circuit diagram of an exemplary code output unit 600 capable of being implemented in the apparatus of FIG. 1 according to one embodiment. In FIG. 7, the code output unit 600 can be configured to include the plurality of flip-flops 610 to 650. Here, each of the a plurality of flip-flops 610 to 650 can receive a bit reserved code signal ‘RCODE’ through its input terminal D and an external clock signal ‘EXT_CLK’ through its clock terminal. Although all of the plurality of flip-flops 610 to 650 can be used, the flip-flops 610 and 620, which can receive the lower two bits of the reserved code signal ‘RCODE’, can be removed to prevent an increase of the size and signal loading of the circuit block receiving the temperature/voltage variation detection code signal ‘VOLTE’ and complication of circuit construction.

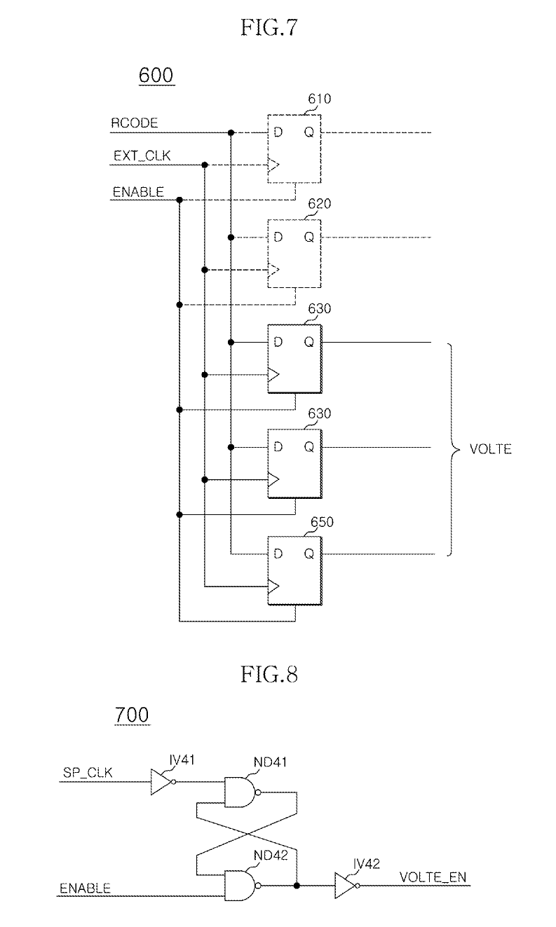

FIG. 8 is a schematic circuit diagram of an exemplary code valid signal generator 700 capable of being implemented in the apparatus of FIG. 1 according to one embodiment. In FIG. 8, the code valid signal generator 700 can be configured to include a plurality of inverters IV41 and IV42 and a plurality of NAND gates ND41 and ND42.

The code valid signal generator 700 can activate the code valid signal ‘VOLTE_EN’ when the enable signal ‘ENABLE’ and the timing control clock signal ‘SP_CLK’ are activated. In addition, the code valid signal generator 700 can inactivate the code valid signal ‘VOLTE_EN’ when the enable signal ‘ENABLE’ is inactivated.

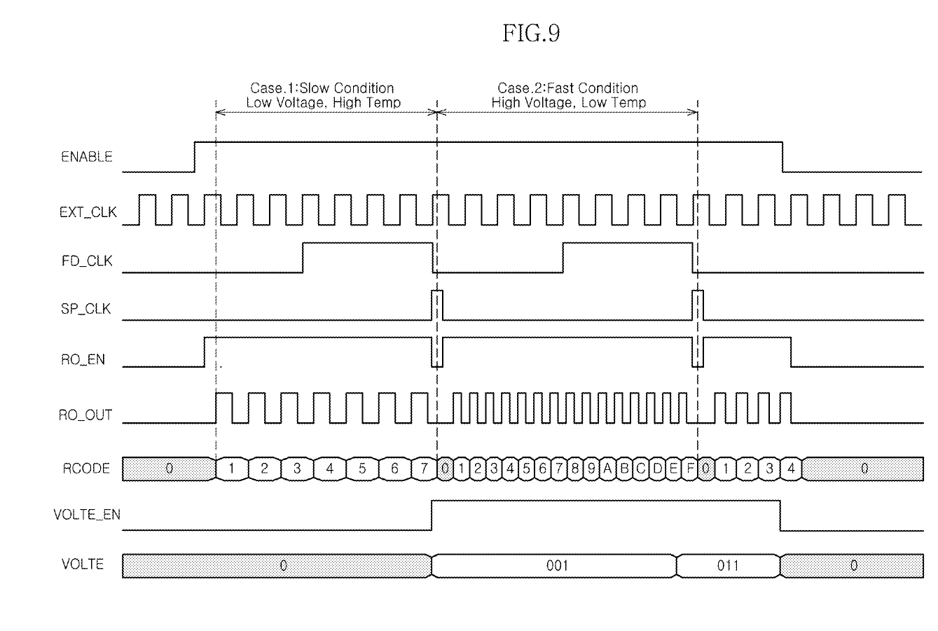

FIG. 9 is a view illustrating exemplary waveforms output from an apparatus for detecting temperature/voltage variations of a semiconductor IC according to one embodiment. An exemplary operation of the apparatus for detecting temperature/voltage variation of the semiconductor IC will be described with reference to FIG. 9.

The driver 100a (in FIG. 2A) or the driver 200b (in FIG. 2B) can generate the enable signal ‘ENABLE’ to be synchronous with the external clock signal ‘EXT_CLK’ to activate the driving signal ‘RO_EN’. The timing control clock signal ‘SP_CLK’ can remain inactivated upon initial operation. Next, the oscillator 200 (in FIG. 3) can generate the oscillation signal ‘RO_OUT’ in response to the driving signal ‘RO_EN’. Then, the code generator 300 (in FIG. 4) can count signal pulses of the oscillation signal ‘RO_OUT’ to output the reserved code signal ‘RCODE’.

In the meanwhile, the divider 400 (in FIG. 5) can divide the external clock signal ‘EXT_CLK’ during a time period where the enable signal ‘ENABLE’ can be activated to generate the division clock signal ‘FD_CLK’, and the timing control clock generator 500 (in FIG. 6) can generate the timing control clock signal ‘SP_CLK’ at a falling edge of the division clock signal ‘FD_CLK’.

The code output unit 600 (in FIG. 7) can latch the reserved code signal ‘RCODE’ whenever the timing control clock signal ‘SP_CLK’ is generated, and can output the remaining bits other than the lower two bits of the latched reserved code signal ‘RCODE’ as the temperature/voltage variation detection code signal ‘VOLTE’.

In FIG. 9, the reserved code signal ‘RCODE’ can be initialized whenever the timing control clock signal ‘SP_CLK’ is generated. In addition, the first driver 100a (in FIG. 2A) or the second driver 100b (in FIG. 2B) can inactivate the driving signal ‘RO_EN’ during a time period where the timing control clock signal ‘SP_CLK’ is within a high level period.

As the driving signal ‘RO_EN’ is inactivated, the oscillator 200 (in FIG. 3) can stop its oscillation operation. For example, operating the oscillator 200 during the time period where the enable signal ‘ENABLE’ is inactivated or the reserved code signal ‘RCODE’ is initialized is not needed. Accordingly, the oscillation operation of the oscillator 200 can stop in order to minimize power consumption.

The code valid signal generator 700 (in FIG. 8) can activate the code valid signal ‘VOLTE_EN’ during a time period from a point when the timing control clock signal ‘SP_CLK’ is generated to a point when the enable signal ‘ENABLE’ is inactivated.

The temperature/voltage variation detection code signal ‘VOLTE’ can have a predetermined voltage level, for example, a low level, before the timing control clock signal ‘SP_CLK’ is generated, i.e., the oscillation signal ‘RO_OUT’ is completed to count. For example, the overall bits of the temperature/voltage variation detection code signal ‘VOLTE’ can come to have a logical value of ‘0’.

However, the valid temperature/voltage variation detection code signal ‘VOLTE’, i.e. the temperature/voltage variation detection code signal ‘VOLTE’ generated after the count of the oscillation signal ‘RO_OUT’ is completed, can be output through the code output unit 600 from the point when the timing control clock signal ‘SP_CLK’ is generated. Since the code valid signal ‘VOLTE_EN’ can be activated and output from the point when the timing control clock signal ‘SP_CLK’ is generated, the validity of the temperature/voltage variation detection code signal ‘VOLTE’ can be determined according to the code valid signal ‘VOLTE_EN’ by the circuit block that receives the temperature/voltage variation detection code signal ‘VOLTE’.

In FIG. 9, a low-frequency oscillation signal ‘RO_OUT’ can be output since the transition delay of the oscillator 200 increases in the case of a first condition (Case.1), i.e., a condition of low voltage and high temperature. Accordingly, the code generator 300 can count seven pulses of the oscillation signal ‘RO_OUT’ to output the reserved code signal ‘RCODE’ as --00111--, and the code output unit 600 can output the remaining bits, i.e., --001--, other than the lower two bits of the reserved code signal ‘RCODE’, as the temperature/voltage variation detection code signal ‘VOLTE’.

Conversely, a high-frequency oscillation signal ‘RO_OUT’ compared to that of the first condition can be output since the transition delay of the oscillator 200 decreases in case of a second condition (Case.2), i.e., a condition of high voltage and low temperature. Accordingly, the code generator 300 can count fifteen pulses of the oscillation signal ‘RO_OUT’ to output the reserved code signal ‘RCODE’ as --01111--, and the code output unit 600 can output the remaining bits, i.e., --011--, other than the lower two bits of the reserved code signal ‘RCODE’, as the temperature/voltage variation detection code signal ‘VOLTE’.

Accordingly, the code value of the temperature/voltage variation detection code signal ‘VOLTE’ can be larger in the second condition (Case.2) than in the first condition (Case.1). Thus, a range for code values of the temperature/voltage variation detection code signal ‘VOLTE’ corresponding to the first case (Case.1) and the second case (Case.2) can be defined through simulation and the temperature and voltage variation of the semiconductor IC can be determined according to a range which includes the code values for the temperature/voltage variation detection code signal ‘VOLTE’ output in actual operating environments. Alternatively, the temperature and voltage variation of the semiconductor IC can be determined through a code table produced according to each operation condition for the temperature/voltage variation detection code signal ‘VOLTE’ through simulation.

The temperature/voltage variation detection code signal ‘VOLTE’ and the code valid signal ‘VOLTE_EN’ can be output to the circuit blocks in the semiconductor IC and used as a criterion to compensate for signal timing. For example, the signal delay time can be adjusted to correspond to the code values of the temperature/voltage variation detection code signal ‘VOLTE’. In addition, the temperature/voltage variation detection code signal ‘VOLTE’ and the code valid signal ‘VOLTE_EN’ can be output to an exterior of the semiconductor IC and used as a criterion to compensate for signal input/output control timing with the semiconductor IC.

While certain embodiments have been described above, it will be understood that the embodiments described are by way of example only. Accordingly, the device and methods described herein should not be limited based on the described embodiments. Rather, the device and methods described herein should only be limited in light of the claims that follow when taken in conjunction with the above description and accompanying drawings.

What is claimed is:

1. An apparatus for detecting temperature/voltage variations of a semiconductor integrated circuit, comprising:
an oscillator configured to generate an oscillation signal whose frequency is varied according to temperature/voltage variations; and
a code generator configured to generate a code signal using the oscillation signal,
wherein the code signal is used as a criterion for detecting the temperature/voltage variations in a circuit construction exterior of the apparatus for detecting the temperature/voltage variations.

2. The apparatus for detecting temperature/voltage variation of a semiconductor integrated circuit of claim 1, wherein the code generator is configured to generate the code signal according to a count value obtained by counting the oscillation signal.

3. The apparatus for detecting temperature/voltage variation of a semiconductor integrated circuit of claim 1, further comprising:
a divider configured to generate a division clock signal by dividing an external clock signal by a predetermined division ratio;
a timing control clock generator configured to generate a timing control clock signal for each cycle of the division clock signal; and
a code output unit configured to latch and output the code signal according to the timing control clock signal.

4. The apparatus for detecting temperature/voltage variation of a semiconductor integrated circuit of claim 3, wherein the code generator is configured to initialize the code signal after a predetermined delay time from a time point when the timing control signal is generated.

5. The apparatus for detecting temperature/voltage variation of a semiconductor integrated circuit of claim 3, wherein the code generator includes a plurality of flip-flops, each receiving the timing control clock signal delayed by a delay component as a reset signal.

6. The apparatus for detecting temperature/voltage variation of a semiconductor integrated circuit of claim 5, wherein a first one of the plurality of flip-flops receives the oscillation signal through its clock terminal, and a second one of the plurality of flip-flops receives an output signal from another one of the plurality of flip-flops located immediately before the first one of the plurality of flip-flops through its clock terminal.

7. The apparatus for detecting temperature/voltage variation of a semiconductor integrated circuit of claim 3, wherein the divider includes a plurality of flip-flops.

8. The apparatus for detecting temperature/voltage variation of a semiconductor integrated circuit of claim 7, wherein a first one of the plurality of flip-flops receives the external clock signal through its clock terminal, and a second one of the plurality of flip-flops receives an output signal from another one of the plurality of flip-flops located immediately before the first one of the plurality of flip-flops through its clock terminal.

9. The apparatus for detecting temperature/voltage variation of a semiconductor integrated circuit of claim 8, wherein the division clock signal is output through the output terminal of a last one of the plurality of flip-flops.

10. The apparatus for detecting temperature/voltage variation of a semiconductor integrated circuit of claim 3, wherein the timing control clock generator is configured to generate the timing control clock signal having a pulse width corresponding to a delay time of a delay component at a timing when a falling edge is generated in the division clock signal.

11. The apparatus for detecting temperature/voltage variation of a semiconductor integrated circuit of claim 3, wherein the code output unit includes a plurality of flip-flops, each receiving the remaining signal bits other than predetermined signal bits of the code signal through its input terminal and receiving the timing control clock signal through its clock terminal.

12. An apparatus for detecting temperature/voltage variation of a semiconductor integrated circuit, comprising:
a driver configured to generate a driving signal according to an enable signal and a timing control clock signal;
an oscillator configured to generate an oscillation signal during a period where the driving signal is activated;
a code generator configured to output a value obtained by counting the oscillation signal as a reserved code signal; and
a code output unit configured to latch one of a whole and partial bits of the reserved code signal according to the timing control clock signal, and to output the latched result as a temperature/voltage variation detection code signal.

13. The apparatus for detecting temperature/voltage variation of a semiconductor integrated circuit of claim 12, wherein the driver is configured to activate the driving signal from a time point when the enable signal is activated to a time point when the timing control clock signal is generated.

14. The apparatus for detecting temperature/voltage variation of a semiconductor integrated circuit of claim 12, wherein the driver is configured to make the enable signal synchronous with the external clock signal during a period where the timing control clock signal is inactivated, and to output the result as the driving signal.

15. The apparatus for detecting temperature/voltage variation of a semiconductor integrated circuit of claim 12, wherein the code generator is configured to generate a value obtained by counting the oscillation signal until a time point before the timing control clock signal is generated as the reserved code signal, and to initialize the reserved code signal after a predetermined delay time from a time point when the timing control clock signal is generated.

16. The apparatus for detecting temperature/voltage variation of a semiconductor integrated circuit of claim 12, wherein the code generator includes a plurality of flip-flops, each of which outputs the reserved code signal through its output terminal and receives the timing control clock signal delayed by a delay component as a reset signal.

17. The apparatus for detecting temperature/voltage variation of a semiconductor integrated circuit of claim 16, wherein a first one of the plurality of flip-flops receives the oscillation signal through its clock terminal, and a second one of the plurality of flip-flops receives an output signal from another one of the plurality of flip-flops located immediately before the first one of the plurality of flip-flops through its clock terminal.

18. The apparatus for detecting temperature/voltage variation of a semiconductor integrated circuit of claim 12, wherein the code output unit includes a plurality of flip-flops that correspond to the number of overall bits of the reserved code signal.

19. The apparatus for detecting temperature/voltage variation of a semiconductor integrated circuit of claim 18, wherein each of the plurality of flip-flops receives the reserved code signal through its input terminal and receives the timing control clock signal through its clock terminal.

20. The apparatus for detecting temperature/voltage variation of a semiconductor integrated circuit of claim 12, wherein the code output unit includes a plurality of flip-flops, each receiving the remaining bits other than predetermined lower bits of the reserved code signal through its input terminal and receives the timing control clock signal through its clock terminal.

21. The apparatus for detecting temperature/voltage variation of a semiconductor integrated circuit of claim 12, further comprising:
a divider configured to divide an external clock signal by a predetermined division ratio to generate a division clock signal;
a timing control clock generator configured to generate a timing control clock signal for each cycle of the division clock signal; and
a code valid signal generator configured to generate a code valid signal for defining validity of the temperature/voltage variation detection code signal using the enable signal and the timing control clock signal.

22. The apparatus for detecting temperature/voltage variation of a semiconductor integrated circuit of claim 21, wherein the divider includes a plurality of flip-flops.

23. The apparatus for detecting temperature/voltage variation of a semiconductor integrated circuit of claim 21, wherein a first one of the plurality of flip-flops receives the external clock signal through its clock terminal, and a second one of the plurality of flip-flops receives an output signal from another one of the plurality of flip-flops located immediately before the first one of the plurality of flip-flops through its clock terminal.

24. The apparatus for detecting temperature/voltage variation of a semiconductor integrated circuit of claim 23, wherein the division clock signal is output through the output terminal of a last one of the plurality of flip-flops.

25. The apparatus for detecting temperature/voltage variation of a semiconductor integrated circuit of claim 21, wherein the timing control clock generator is configured to generate the timing control clock signal having a pulse width corresponding to a delay time of a delay component at a timing when a falling edge is generated in the division clock signal.

26. The apparatus for detecting temperature/voltage variation of a semiconductor integrated circuit of claim 21, wherein the code valid signal generator is configured to generate the code valid signal that is activated from a time point when the timing control clock signal is generated to a time point when the enable signal is inactivated.

27. A method for detecting temperature/voltage variations of a semiconductor integrated circuit, comprising:
generating an oscillation signal; and
generating a code signal using the oscillation signal to output the code signal used as a criterion for detecting temperature/voltage variations of a semiconductor integrated circuit.

28. The method for detecting temperature/voltage variations of a semiconductor integrated circuit of claim 27, wherein the generating the code signal includes generating a count value obtained by counting the oscillation signal as the code signal.

29. The method for detecting temperature/voltage variations of a semiconductor integrated circuit of claim 28, wherein the generating the code signal includes storing the count value according to a timing control clock signal generated in a predetermined period to generate the code signal, and initializing the count value according to the timing control clock signal delayed by a predetermined time.

30. The method for detecting temperature/voltage variations of a semiconductor integrated circuit of claim 29, wherein the generating the oscillation signal is stopped during a period where an enable signal is inactivated and a period where the timing control clock signal is activated to define a period for detecting the temperature/voltage variations.

31. The method for detecting temperature/voltage variations of a semiconductor integrated circuit of claim 27, wherein the outputting the code signal includes outputting one of a whole or a remaining bits other than partial bits of the code signal.

32. The method for detecting temperature/voltage variation of a semiconductor integrated circuit of claim 31, wherein the outputting the code signal further includes outputting a code valid signal for defining validity of the code signal.

33. The method for detecting temperature/voltage variations of a semiconductor integrated circuit of claim 32, wherein the code valid signal is activated during a period after a time point when the timing control clock signal is generated in a period where the enable signal is activated.
